(19) United States
(12) Patent Application Publication
(10) Pub. No.: US 2025/0107057 A1
(43) Pub. Date: Mar. 27, 2025

(54) FEEDER, COMPONENT MOUNTING MACHINE, AND COMPONENT MOUNTING METHOD

(71) Applicant: FUJI CORPORATION, Chiryu (JP)

(72) Inventor: Hiroki MURASE, Nagoya-shi (JP)

(73) Assignee: FUJI CORPORATION, Chiryu (JP)

(21) Appl. No.: 18/728,167

(22) PCT Filed: Feb. 14, 2022
(86) PCT No.: PCT/JP2022/005636

§ 371 Date: Jul. 11, 2024

(51) Int. Cl. H05K 13/04

(52) U.S. Cl. CPC H05K 13/0419

(57) ABSTRACT

A feeder that is arranged in multiples side by side and detachably attached to a component mounting machine, the feeder being for feeding a tape accommodating components to supply the components, the feeder includes a feeder main body including a holding section configured to hold a reel around which the tape is wound, and a plate-shaped cover configured to open and close the holding section by rotation via a support shaft. Further, the cover includes an inclined section that has an inclined surface inclined toward the feeder main body with respect to an outer surface of the cover and is provided at an end portion on a front side in an attachment direction of the feeder to the component mounting machine.

### TECHNICAL FIELD

The present description discloses a feeder, a component mounting machine, and a component mounting method.

### BACKGROUND ART

Conventionally, a feeder is known to which a reel around which a tape accommodating components is wound is attached and which feeds the tape and supplies the components by rotating the reel. For example, Patent Literature 1 discloses an apparatus including a reel holder that holds a reel, a cover that covers at least a part of the reel in the reel holder, a displacement mechanism that holds the reel holder to be displaceable in a width direction with respect to a feeder main body, and a bumper section provided to a tapered shape at a front end portion of the feeder main body. When the feeder is attached to a component mounting machine, a bumper section first comes into contact with a reel holder of an adjacent feeder and displaces the reel holder of the adjacent feeder, and thereby, feeders can be prevented from strongly colliding with each other.

### PATENT LITERATURE

Patent Literature 1: WO2019/229824A1

### BRIEF SUMMARY

### Technical Problem

As described above, contact with an adjacent feeder when a feeder is attached to or detached from a component mounting machine can become a problem. For example, when a cover is not reliably locked, the feeder is attached to the component mounting machine in a state where the cover is half-opened, and accordingly, the cover can strongly collide with the adjacent feeder, thereby damaging the feeder. Further, in a configuration in which a reel holder is displaced, the reel holder can come into contact with an adjacent feeder and rub against the feeder, and when the reel holder continuously rubs against the feeder, a surface thereof can be greatly worn, and the feeder can be damaged.

A main object of the present disclosure is to prevent a feeder from being damaged due to contact between adjacent reels.

### Solution to Problem

The present disclosure employs following technology to achieve the main object described above.

A feeder of the present disclosure is a feeder that is arranged in multiples side by side and detachably attached to a component mounting machine, the feeder being for feeding a tape accommodating components to supply the components, the feeder including:
a feeder main body including a holding section configured to hold a reel around which the tape is wound, and
a plate-shaped cover configured to open and close the holding section by rotation via a support shaft, in which
the cover includes an inclined section that has an inclined surface inclined toward the feeder main body with respect to an outer surface of the cover and is provided at an end portion on a front side in an attachment direction of the feeder to the component mounting machine.

According to the feeder of the present disclosure, even in a case where the cover is in a half-open state when the feeder is attached to a component mounting machine, the inclined section on the front side is in contact with an adjacent feeder, and thus, the feeder can be prevented from being damaged.

### BRIEF DESCRIPTION OF DRAWINGS

FIG. 1 is a configuration view schematically illustrating a configuration of component mounting machine 10.

FIG. 2 is a configuration view schematically illustrating a configuration of tape feeder 20.

FIG. 3 is a configuration view schematically illustrating the configuration of tape feeder 20.

FIG. 4 is a perspective view schematically illustrating a configuration of a rear portion of tape feeder 20.

FIG. 5 is a view schematically illustrating the configuration of the rear portion of tape feeder 20.

FIG. 6 is a view schematically illustrating a configuration of a front portion of reel cover 30.

FIG. 7 is a view illustrating an example of a state where tape feeder 20 is attached.

FIG. 8 is a view illustrating the example of the state where tape feeder 20 is attached.

FIG. 9 is a view illustrating the example of the state where tape feeder 20 is attached.

### DESCRIPTION OF EMBODIMENTS

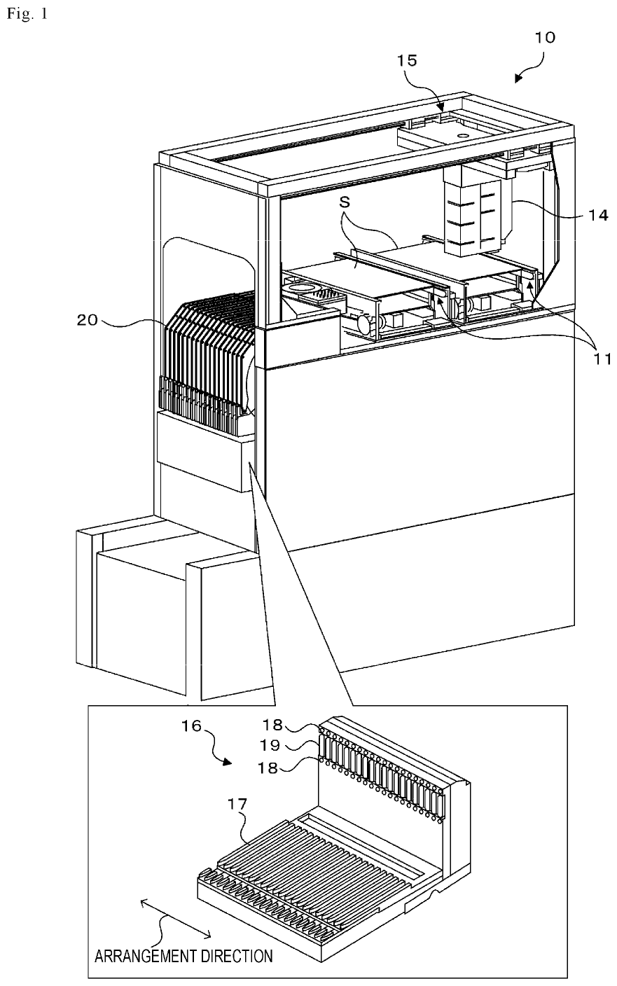

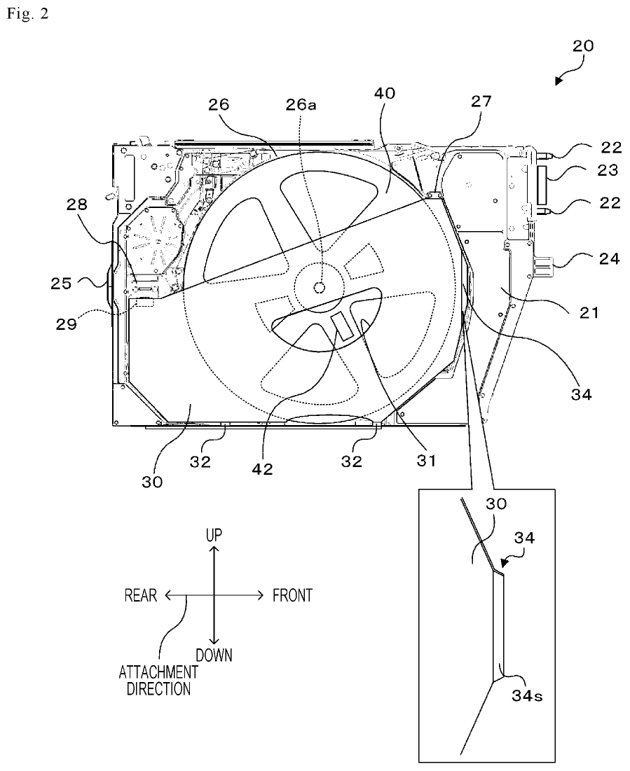

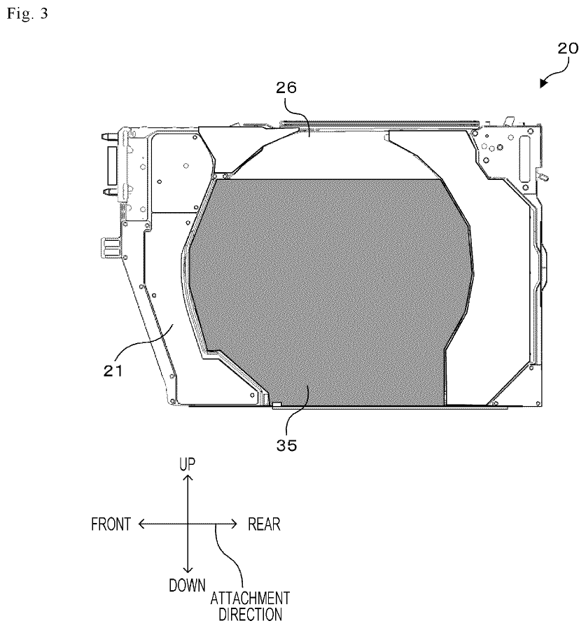

Next, embodiments of the present disclosure will be described with reference to the drawings. FIG. 1 is a configuration view schematically illustrating a configuration of component mounting machine 10. FIGS. 2 and 3 are configuration views schematically illustrating configurations of tape feeder 20. FIG. 2 illustrates a configuration of a front surface side of tape feeder 20, and FIG. 3 illustrates a configuration of a rear surface side of tape feeder 20. As illustrated in FIG. 1, component mounting machine 10 includes board conveyance device 11 that conveys board S, tape feeder 20 that supplies a component, head 14 in which a nozzle that picks up the component is disposed to be able to be lifted and lowered, and movement device 15 that moves head 14 in XY directions. Board conveyance device 11 has two pairs of conveyor belts and conveys board S by each conveyor belt.

Tape feeder 20 supplies components by feeding, for example, a tape, in which the components are accommodated at a predetermined pitch, to a supply position where the nozzle of head 14 can collect the components. Although not illustrated, the tape is configured with a bottom tape in which cavities (recessed section) for accommodating components are formed at predetermined intervals, and a film-like cover tape that covers the bottom tape. In tape feeder 20, reel 40 around which the tape is wound is set, the tape is pulled out from reel 40 and fed out to the supply position, and the cover tape is peeled off from the bottom tape before the supply position, and thereby, the components are in a state of being able to be picked up.

Further, multiple tape feeders 20 are arranged in and attached to feeder stand 16 provided to component mounting machine 10. Feeder stand 16 is an L-shaped stand in a side view and includes multiple slots 17, two positioning holes 18 corresponding to each slot 17, and connector 19 corresponding to each slot 17. Attachment of tape feeder 20 to feeder stand 16 is made by inserting tape feeder 20 into slot 17 and sliding tape feeder 20. In component mounting machine 10, multiple types of components are supplied from multiple tape feeders 20 attached to feeder stand 16, and each of the supplied components is collected by the nozzle of head 14 and can be mounted on board S.

As illustrated in FIG. 2, tape feeder 20 includes feeder main body 21 provided with reel holder 26 that holds reel 40, and plate-shaped reel cover 30 that opens and closes reel holder 26.

Reel holder 26 is configured to hold multiple types of reels 40 having different sizes to be rotatable about a central axis, and holding shaft 26a for holding the central axis of reel 40 is provided to a central portion thereof. Further, reel holder 26 is provided to be displaceable with respect to feeder main body 21 in an arrangement direction (see FIG. 1) that is a direction in which tape feeder 20 is arranged on feeder stand 16. Although not illustrated in the drawings, reel holder 26 has, for example, a recess into which a protrusion of feeder main body 21 is loosely fitted and which is formed in a lower portion thereof, and has a protrusion which is loosely fitted into a recess of feeder main body 21 and is formed in an upper portion thereof, and is displaceable with respect to feeder main body 21 by the loosely fitting of the protrusion into the recess. Since the displaceable configuration is described in WO 2019/229824A1 of the applicant of the present application, detailed description thereof is omitted. A width of feeder main body 21, that is, a thickness in the arrangement direction is set to be smaller than pitches of slots 17 of feeder stand 16, but a width of reel holder 26 is set to be larger than the width of feeder main body 21. Accordingly, when tape feeder 20 is attached to or detached from feeder stand 16 in a state where reel holder 26 is displaced, reel holder 26 may come into contact with and rub against adjacent tape feeder 20.

In feeder main body 21, two positioning pins 22 and connector 23 are provided at an end portion on a front side in an attachment direction (see FIG. 2) of tape feeder 20 to feeder stand 16 to protrude toward the front in the attachment direction. Two positioning pins 22 are respectively inserted into two positioning holes 18 of feeder stand 16. Connector 23 is provided between two positioning pins 22 and is connected to connector 19 of feeder stand 16.

Further, in feeder main body 21, front bumper 24 that protrudes forward to prevent collision is provided at a front end portion in an attachment direction. Although detailed illustration of front bumper 24 is omitted, front bumper 24 is formed in a triangular shape in a top view such that a front end side thereof has a tapered shape. Accordingly, when tape feeder 20 is attached to feeder stand 16, even when reel holder 26 of adjacent tape feeder 20 is displaced, front bumper 24 comes into contact with reel holder 26 and can displace reel holder 26 to be accommodated in adjacent tape feeder 20. Thereby, when tape feeder 20 is attached, reel holder 26 of adjacent tape feeder 20 can be prevented from strongly colliding and being damaged.

Furthermore, as illustrated in FIG. 3, feeder main body 21 is provided with seal member 35 on a rear surface side. Seal member 35 is formed to have substantially the same size as a rear surface region of reel holder 26 and is attached thereto. Seal member 35 is formed of a resin material with wear resistance and slide property, such as ultra-high molecular weight polyethylene with excellent wear resistance and slide property. Seal member 35 may be provided not only in the rear surface region of reel holder 26 but also in a part or entire of a rear surface region of feeder main body 21.

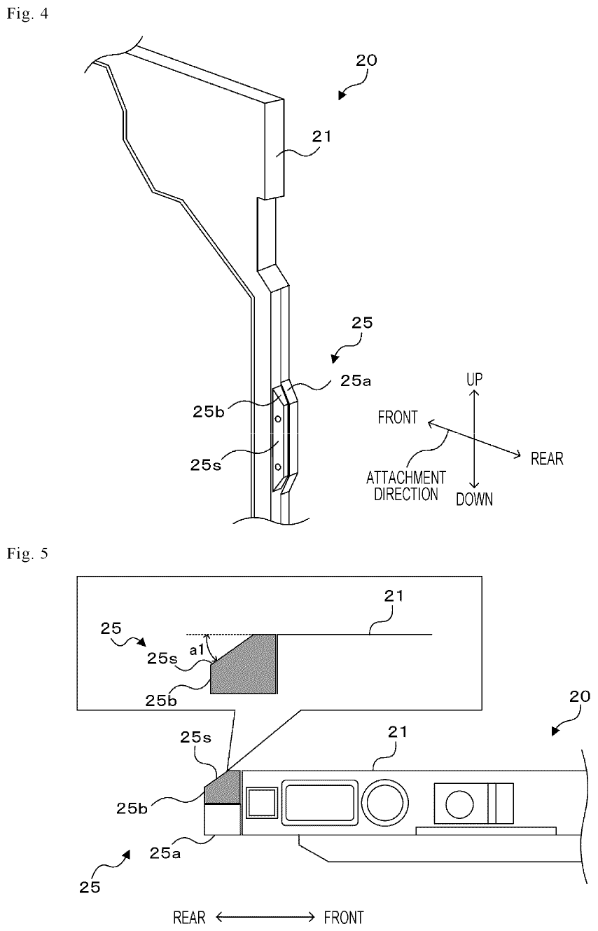

FIG. 4 is a perspective view schematically illustrating a configuration of a rear portion of tape feeder 20. FIG. 5 is a view schematically illustrating the configuration of the rear portion of tape feeder 20. As illustrated in the drawings, in feeder main body 21, rear bumper 25 that protrudes rearward is provided to prevent collision at a rear end portion in the attachment direction. Rear bumper 25 includes metal base section 25a located on a front surface side of tape feeder 20 and provided integrally with feeder main body 21, and resin contact section 25b located on a rear surface side and fixed to base section 25a by screwing. That is, in rear bumper 25, contact section 25b is provided on the rear surface side opposite to reel cover 30. Further, contact section 25b has tapered surface 25s formed such that a thickness in the arrangement direction (see FIG. 1) of tape feeders 20 decreases toward the rear which is a protruding end side. Contact section 25b is formed such that inclined angle a1 of tapered surface 25s becomes an acute angle of, for example, about 30 degrees to 45 degrees with respect to a rear surface of feeder main body 21.

Reel cover 30 is a plate-shaped member that opens and closes reel holder 26 by rotating via support shaft 32 provided at a lower portion, and enables reel 40 to be attached to and detached from reel holder 26 in an open state. Reel cover 30 is formed of a single metal plate, and is formed in a size that covers from a lower end of reel holder 26 to above holding shaft 26a in a closed state and exposes an upper portion of reel holder 26. That is, reel cover 30 is formed in a size that covers at least half of a board surface region of reel 40 held by reel holder 26. Further, opening 31 is formed in reel cover 30. Here, identification code 42, such as a bar code or a two-dimensional code for reading identification information, such as the type of component, is given to reel 40. Identification code 42 can be read by being exposed from above reel cover 30 or being exposed from opening 31 by rotating reel 40.

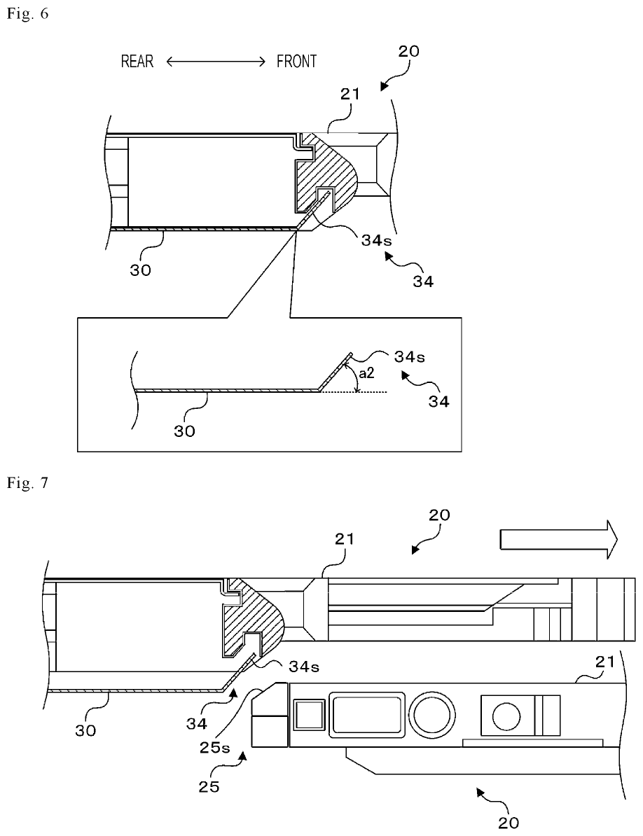

FIG. 6 is a view schematically illustrating a configuration of a front portion of reel cover 30. In reel cover 30, collision prevention wing 34 is provided on an end portion on a front side in the attachment direction. Collision prevention wing 34 has inclined surface 34s inclined at an acute angle toward feeder main body 21 side with respect to a plate surface (outer surface) of reel cover 30. Collision prevention wing 34 is formed by bending a part of the end portion on the front side of reel cover 30 such that inclined angle a2 of inclined surface 34s becomes an angle of, for example, about 30 degrees to 45 degrees.

Tape feeder 20 includes lock mechanism 27 on a front side in an attachment direction of tape feeder 20 and lock mechanism 28 on a rear side in the attachment direction of tape feeder 20 as a lock mechanism that locks reel cover 30. Although detailed illustration is omitted, lock mechanisms 27 and 28 are configured to lock reel cover 30 when an operator pushes reel cover 30 toward each of lock mechanisms 27 and 28, and to release the lock when the operator pushes a release lever upward. Further, magnet 29 for picking up reel cover 30 is provided inside lock mechanism 28 on the rear side. Meanwhile, a magnet is not provided to lock mechanism 27 on the front side. This is to prevent the locking of reel cover 30 from being disturbed as a component dropped from the tape near the supply position is picked up to the magnet of lock mechanism 27 and held there.

A case where tape feeder 20 configured as described above is attached to feeder stand 16 will be described. FIGS. 7 to 9 are views illustrating examples of states where tape feeder 20 is attached. Here, a state in which tape feeder 20 on an upper side to be attached later slides in a state where adjacent tape feeder 20 (tape feeder 20 on a lower side in FIGS. 7 to 9) is first attached is illustrated. Tape feeder 20 to be attached later is in a half-open state in which reel cover 30 is not reliably locked. Accordingly, as illustrated in FIG. 7, reel cover 30 is slid in the attachment direction (a direction of a white arrow) while remaining in the half-open state.

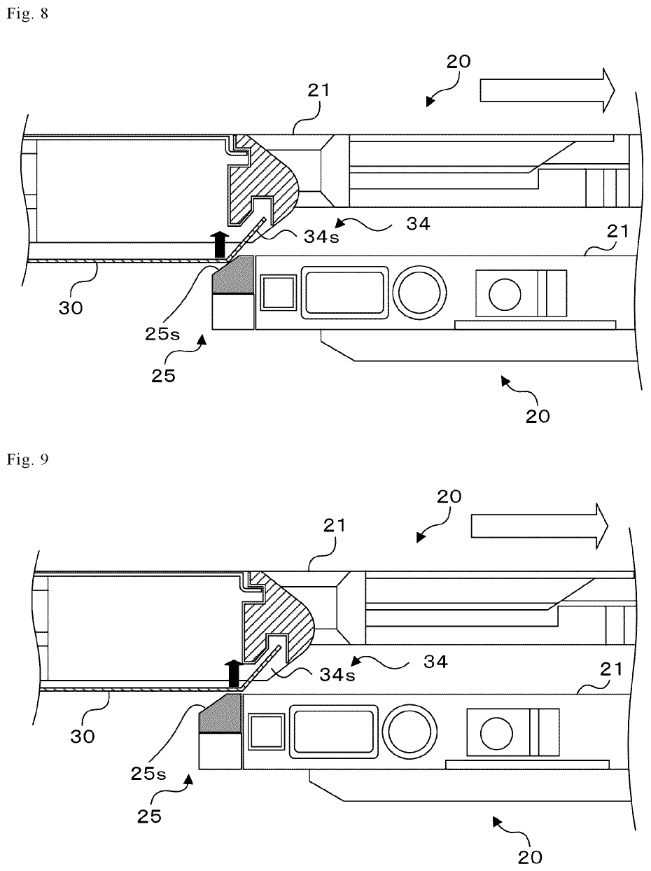

Then, as illustrated in FIG. 8, inclined surface 34s of collision prevention wing 34 of reel cover 30 comes into contact with tapered surface 25s of rear bumper 25 of adjacent tape feeder 20. That is, when reel cover 30 is in the half-open state, inclined surface 34s first comes into contact with adjacent tape feeder 20. Accordingly, a component force received by inclined surface 34s acts on reel cover 30 and moves reel cover 30 in a closing direction (a direction of a black arrow), and it is possible to appropriately prevent tape feeders 20 from strongly colliding with each other (see FIGS. 8 and 9). In this way, when tape feeder 20 in which reel cover 30 is in the half-open state is attached, reel cover 30 is moved in the closing direction by the force received by being in contact with adjacent tape feeder 20, and thus tape feeder 20 can be prevented from being damaged.

Further, as described above, seal member 35 is provided on a rear surface of reel holder 26. Here, when the rear surface of reel holder 26 continuously rubs against reel cover 30 or the like of adjacent tape feeder 20, abrasive wear occurs, and deep scratches occur on a surface, which may damage an appearance of tape feeder 20. In the present embodiment, by providing seal member 35 with wear resistance, occurrence of the wear can be reduced to prevent damage. Further, since seal member 35 has slide property, sliding resistance can be prevented from increasing when tape feeder 20 is attached and detached, and slide property can be prevented from being damaged. When wear or damage of seal member 35 increases, the operator may replace seal member 35.

Here, a correspondence relationship between elements of the present embodiment and elements of the present disclosure will be clarified. Tape feeder 20 of the present embodiment corresponds to a feeder, reel holder 26 corresponds to a holding section, feeder main body 21 corresponds to a feeder main body, reel cover 30 corresponds to a cover, and collision prevention wing 34 corresponds to an inclined section. Rear bumper 25 corresponds to a protrusion section. Lock mechanism 27 corresponds to a front lock mechanism, lock mechanism 28 corresponds to a rear lock mechanism, and magnet 29 corresponds to a magnet. Seal member 35 corresponds to a seal member. Head 14 corresponds to a mounting head, and component mounting machine 10 corresponds to a component mounting machine. In the present embodiment, an example of a component mounting method of the present disclosure is also clarified.

In tape feeder 20 of the present embodiment described above, even when reel cover 30 is in the half-open state when being attached to feeder stand 16 of component mounting machine 10, collision prevention wing 34 comes into contact with adjacent tape feeder 20 to be able to move reel cover 30 in the closing direction. Accordingly, even when reel cover 30 is in the half-open state, tape feeder 20 can be prevented from being damaged by preventing reel cover 30 from strongly colliding with adjacent tape feeder 20.

Further, rear bumper 25 of tape feeder 20 has tapered surface 25s formed on a rear surface opposite to reel cover 30 such that the thickness in the arrangement direction decreases toward the rear. Accordingly, since inclined surface 34s of collision prevention wing 34 comes into contact with tapered surface 25s of rear bumper 25, reel cover 30 in the half-open state and adjacent tape feeder 20 can be more reliably prevented from strongly colliding with each other.

Further, lock mechanism 28 on the rear side is provided with magnet 29 for picking up reel cover 30, while lock mechanism 27 on the front side is not provided with a magnet for picking up reel cover 30. Accordingly, since reel cover 30 is in the half-open state when the operator forgets to lock the lock mechanism 27 on the front side, significance of applying the present disclosure is high.

Further, since seal member 35 is provided on the rear surface of reel holder 26, wear can be reduced, and damage can be prevented. Further, since seal member 35 has slide property, it is possible to prevent reduction of the slide property of tape feeder 20.

The present disclosure is not limited to the embodiments described above, and it goes without saying that the present disclosure can be implemented in various ways as long as the present disclosure is in the technical scope of the present disclosure.

For example, in the above-described embodiments, although rear bumper 25 includes metal base section 25a and resin contact section 25b, the embodiments are not limited thereto, and rear bumper 25 may be entirely configured with a single member such as a resin single member and attached to feeder main body 21. Further, a resin plate or the like may be attached to inclined surface 34s (contact surface) of collision prevention wing 34 of reel cover 30.

In the embodiments described above, collision prevention wing 34 is provided to reel cover 30, and rear bumper 25 is provided to feeder main body 21, but the embodiments are not limited thereto. While collision prevention wing 34 is provided to reel cover 30, rear bumper 25 need not be provided to feeder main body 21. Alternatively, while rear bumper 25 is provided to feeder main body 21, collision prevention wing 34 need not be provided to reel cover 30. When either one of collision prevention wing 34 and rear bumper 25 is provided, and when reel cover 30 in the half-open state comes into contact with adjacent tape feeder 20, reel cover 30 can be moved in the closing direction, and accordingly, tape feeders 20 can be appropriately prevented from strongly colliding with each other. Further, although a configuration in which front bumper 24 is provided is exemplified, front bumper 24 is not an essential configuration, and front bumper 24 need not be provided.

In the embodiment described above, seal member 35 is provided on the rear surface side of feeder main body 21 (reel holder 26), but the embodiment is not limited thereto, and seal member 35 may be provided on a front surface side of feeder main body 21, that is, reel cover 30. Alternatively, seal member 35 is not limited to being provided, and seal member 35 need not be provided.

In the embodiments described above, although magnet 29 is provided only to lock mechanism 28 on the rear side, the embodiments are not limited thereto, and a magnet may be provided to lock mechanism 27 on the front side. However, as described above, it is preferable that magnet 29 is not provided to prevent a dropped component from being picked up. Further, magnet 29 need not be provided to any of lock mechanisms 27 and 28 in the front and rear.

In the embodiments described above, a structure for preventing collision of reel cover 30 in the half-open state includes collision prevention wing 34 and rear bumper 25, and furthermore, seal member 35 is provided on a rear surface side of reel holder 26, but the embodiments are not limited thereto. That is, seal member 35 may be provided on the rear surface side of reel holder 26 without providing the structure for preventing collision of reel cover 30. Even in this case, damage due to wear of reel holder 26 can be prevented.

### INDUSTRIAL APPLICABILITY

The present disclosure can be used in a field of component mounting and the like.

### REFERENCE SIGNS LIST

10 component mounting machine, 11 board conveyance device, 14 head, 15 movement device, 16 feeder stand, 17 slot, 18 positioning hole, 19 connector, 20 tape feeder, 21 feeder main body, 22 positioning pin, 23 connector, 24 front bumper, 25 rear bumper, 25a base section, 25b contact section, 25s tapered surface, 26 reel holder, 26a holding shaft, 27, 28 lock mechanism, 29 magnet, 30 reel cover, 31 opening, 32 support shaft, 34 collision prevention wing, 34s inclined surface, 35 seal member, 40 reel, 42 identification code, S board

1. A feeder that is arranged in multiples side by side and detachably attached to a component mounting machine, the feeder being for feeding a tape accommodating components to supply the components, the feeder comprising:
a feeder main body including a holding section configured to hold a reel around which the tape is wound; and
a plate-shaped cover configured to open and close the holding section by rotation via a support shaft,
wherein the cover includes an inclined section that has an inclined surface inclined toward the feeder main body with respect to an outer surface of the cover and is provided at an end portion on a front side in an attachment direction of the feeder to the component mounting machine.

2. The feeder according to claim 1, wherein
the feeder main body includes a protrusion section protruding toward a rear from an end portion on a rear side in the attachment direction, and
the protrusion section has a tapered surface formed on a side opposite to the cover such that a thickness of the protrusion section in an arrangement direction of the feeder decreases toward the rear.

3. A feeder that is arranged in multiples side by side and detachably attached to a component mounting machine, the feeder being for feeding a tape accommodating components to supply the components, the feeder comprising:
a feeder main body including a holding section configured to hold a reel around which the tape is wound; and
a plate-shaped cover configured to open and close the holding section by rotation via a support shaft,
wherein the feeder main body includes a protrusion section protruding toward a rear from an end portion on a rear side in an attachment direction of the feeder to the component mounting machine, and
the protrusion section has a tapered surface formed on a side opposite to the cover such that a thickness of the protrusion section in an arrangement direction of the feeder decreases toward the rear.

4. The feeder according to claim 1, further comprising:
a lock mechanism configured to lock the cover on each of a front side and a rear side in the attachment direction,
wherein the cover is formed of a metal plate,
the lock mechanism on the rear side includes a magnet for picking up the cover, and
the lock mechanism on the front side does not include the magnet for picking up the cover.

5. The feeder according to claim 1, wherein the feeder main body includes the holding section provided to be displaceable in the arrangement direction of the feeder, and a seal member with slide property which is provided on a rear surface opposite to the cover.

6. A feeder that is arranged in multiples side by side and detachably attached to a component mounting machine, the feeder being for feeding a tape accommodating components to supply the components, the feeder comprising:
a feeder main body including a holding section configured to hold a reel around which the tape is wound and to be displaceable in an arrangement direction of the feeder; and
a plate-shaped cover configured to open and close the holding section,
wherein the feeder main body includes a seal member with slide property on a rear surface opposite to the cover.

7. A component mounting machine comprising:
the feeder according to claim 1; and
a mounting head configured to collect the component supplied from the feeder and mount the component on a target object.

8. A component mounting method comprising:
(a) a step of supplying a component from the feeder according to claim 1; and
(b) a step of collecting the component supplied in the step (a) and mounting the component on a target object.
